(19) United States
(12) Patent Application Publication
(10) Pub. No.: US 2013/0265698 A1
(43) Pub. Date: Oct. 10, 2013

(54) REMOTE CONTROL FOR HIGH HUMIDITY ENVIRONMENTS

(71) Applicants: Matthew R. Baum, Batesville, IN (US); Owen Dong, Shenzhen (CN); Charles V. Edwards, Nashville, IN (US); Lawrence A. May, Greenwood, IN (US); James P. Meagher, Indianapolis, IN (US); Robert D. O'Neil, Indianapolis, IN (US)

(72) Inventors: Matthew R. Baum, Batesville, IN (US); Owen Dong, Shenzhen (CN); Charles V. Edwards, Nashville, IN (US); Lawrence A. May, Greenwood, IN (US); James P. Meagher, Indianapolis, IN (US); Robert D. O'Neil, Indianapolis, IN (US)

(73) Assignee: NIDEC MOTOR CORPORATION, St. Louis, MO (US)

(21) Appl. No.: 13/473,090

(22) Filed: May 16, 2012

(30) Foreign Application Priority Data
Apr. 6, 2012 (CN) 201210127227.3

(51) Int. Cl. H05K 5/02

(52) U.S. Cl. CPC H05K 5/0213
USPC 361/679.01

(57) ABSTRACT

A remote control is provided for use in a high humidity environment. More particularly, the remote control includes a foam insert configured to at least substantially fill a space in an interior compartment of the remote control to prevent formation of condensate in the space. The foam insert is also configured to exert a force against a control board in the interior compartment, thereby fixing the control board within the remote control. The remote control housing comprises a pair of enclosures. A plurality of latch components and a polymer bead are provided to cooperatively secure the enclosures to each other, with the bead providing an at least substantially continuous seal between the interior compartment and the environment.

### RELATED APPLICATION

The present application claims the benefit of and priority from Chinese Patent Application No. 201210127227.3, filed Apr. 26, 2012, the entire disclosure of which is hereby incorporated by reference herein.

### BACKGROUND OF THE INVENTION

1. Field of the Invention

The present invention relates generally to a remote control for use in a high humidity environment. More specifically, a preferred embodiment of the present invention concerns a remote control configured such that water and humid air ingress, internal condensate formation, and signal interference are minimized.

2. Discussion of the Prior Art

Those of ordinary skill in the art will appreciate that remote controls, also referred to as wireless remotes, remotes, and a variety of other names, are commonly used to control one or more devices from a distance, typically through transmission of either infrared (IR) signals or radio frequency (RF) signals. Infrared remote controls are commonly used to control televisions, for instance, while radio frequency remote controls are commonly used to lock or unlock automobile doors. Specialized remote controls for use in or near swimming pools, spas, or other humid environments are also known. For instance, a remote control might be configured to control hot tub jets, swimming pool temperature controls, or a built-in spa stereo system.

Conventional remote controls typically include a plastic housing comprising a pair of enclosures that connect through use of metal screws or plastic latches. The housing protects the internal components of the remote control, which typically include a control board and associated electronic components. In some instances, a display screen that provides a user interface is provided. A battery is usually included, as well, often in a separate compartment within the housing and accessible upon removal of a battery cover to allow user access without exposing the internal electronics. In addition to the above, the housing provides a surface to be held by the user and, for the sake of user comfort, often encompasses a greater volume than would be necessary simply to contain the internal components.

Remote controls that must function in or near water or humid environments are typically configured to avoid or minimize ingress of water into the interior of the remote control to avoid damage of internal electronic components. Humid air ingress is also detrimental, with thermal fluctuations operable to cause formation of condensate from humid internal air. In the case of remote controls having a display screen, water or humid air encroachment can also lead to formation or accumulation of water droplets between the display screen and a protective cover typically placed above it, hindering the user experience.

### SUMMARY

According to one aspect of the present invention, a remote control for use in a high-humidity environment is provided. The remote control comprises a housing, a control board, and a foam insert. The housing defines an interior compartment. The control board is positioned within the interior compartment, with the control board occupying only part of the interior compartment such that an unoccupied remaining portion of the interior compartment is defined. The foam insert is located within the interior compartment such that the insert is positioned at least in part adjacent the control board. The foam insert is resiliently loaded to thereby exert a force against the control board and thus secure the control board within the interior compartment. The foam insert is also configured to at least substantially fill the remaining portion of the interior compartment to thereby at least substantially prevent formation of condensate within the remaining portion of the interior compartment.

According to another aspect of the present invention, a remote control for use in a high-humidity environment is provided. The remote control comprises a housing, a control board, and a polymer bead. The housing comprises a pair of interconnected enclosures that cooperatively define an interior compartment, with the enclosures comprising complementary latch components that secure the enclosures to one another. The control board is positioned within the interior compartment. A first one of the enclosures includes an at least substantially continuous groove that at least substantially circumscribes the interior compartment, while a second one of the enclosures includes an at least substantially continuous projection received within the groove. A polymer bead is formed within the groove such that the bead at least partially encompasses the projection, the bead and the projection thereby cooperating to additionally secure the enclosures to each other and to form an at least substantially continuous seal between the enclosures.

Among other things, provision of a foam insert within the interior compartment and at least in part adjacent the control board, wherein the foam insert is resiliently loaded to thereby exert a force against the control board, allows fixation of the control board within the remote control without the use of fasteners. Exclusion of such fasteners decreases the number of necessary components for construction of the remote and, in the case of fasteners such as conventional metal screws, eliminates the potential for associated interference with control and feedback signals to and from the remote control and the potential for associated cracking of the adjacent portions of the housing and resulting encroachment by humid air or water.

Among other things, provision of a foam insert that at least substantially fills the portion of the interior compartment that remains after inclusion of a control board prevents formation of condensate within the remaining portion of the interior compartment. More particularly, the foam insert fills the space which humid air might otherwise have occupied, thereby eliminating the potential for condensate formation.

Among other things, provision of both a polymer bead between the enclosures and latch components associated with the enclosures allows formation of a more robust connection between the enclosures than would exist using one of the above connection methods exclusively. This may be particularly important in cases in which thermal fluctuations or other factors have, over time, led to creep and weakening of the latch components. Initially, however, provision of latch components allows proper positioning of and securement of the enclosures while the polymer bead is curing during assembly of the remote control. Even further, the polymer bead provides a seal between the enclosures to prevent ingress of water, air, dust, and the like.

This summary is provided to introduce a selection of concepts in a simplified form. These concepts are further described below in the detailed description of the preferred embodiments. This summary is not intended to identify key features or essential features of the claimed subject matter, nor is it intended to be used to limit the scope of the claimed subject matter.

Various other aspects and advantages of the present invention will be apparent from the following detailed description of the preferred embodiments and the accompanying drawing figures.

### BRIEF DESCRIPTION OF THE DRAWING FIGURES

A preferred embodiment of the present invention is described in detail below with reference to the attached drawing figures, wherein:

FIG. 1 is a left rear top isometric view of a remote control constructed in accordance with the principles of a preferred embodiment of the present invention;

FIG. 2 is right front top isometric view of the remote control of FIG. 1;

FIG. 3 is an exploded left rear top isometric view of the remote control of FIGS. 1 and 2, particularly illustrating the arrangement of the internal components;

FIG. 4 is an exploded bottom perspective view of the remote control of FIGS. 1-3, particularly illustrating the internal structure of the upper enclosure;

FIG. 5 is an exploded right front top isometric view of the remote control of FIGS. 1-4, particularly illustrating the relationships between various components;

FIG. 6 is an irregularly sectioned right front top isometric view of the remote control of FIGS. 1-5, particularly illustrating the relative positioning of and interengagement among the internal components, the housing structures, and the sealing structures; and

FIG. 7 is an irregularly sectioned left front top isometric view of the remote control of FIGS. 1-6, particularly illustrating the relative positioning of and interengagement among the housing structures, the sealing structures, and the internal components.

The drawing figures do not limit the present invention to the specific embodiments disclosed and described herein. The drawings are not necessarily to scale, emphasis instead being placed upon clearly illustrating the principles of the preferred embodiments.

### DETAILED DESCRIPTION OF THE PREFERRED EMBODIMENTS

The present invention is susceptible of embodiment in many different forms. While the drawings illustrate, and the specification describes, certain preferred embodiments of the invention, it is to be understood that such disclosure is by way of example only. There is no intent to limit the principles of the present invention to the particular disclosed embodiments.

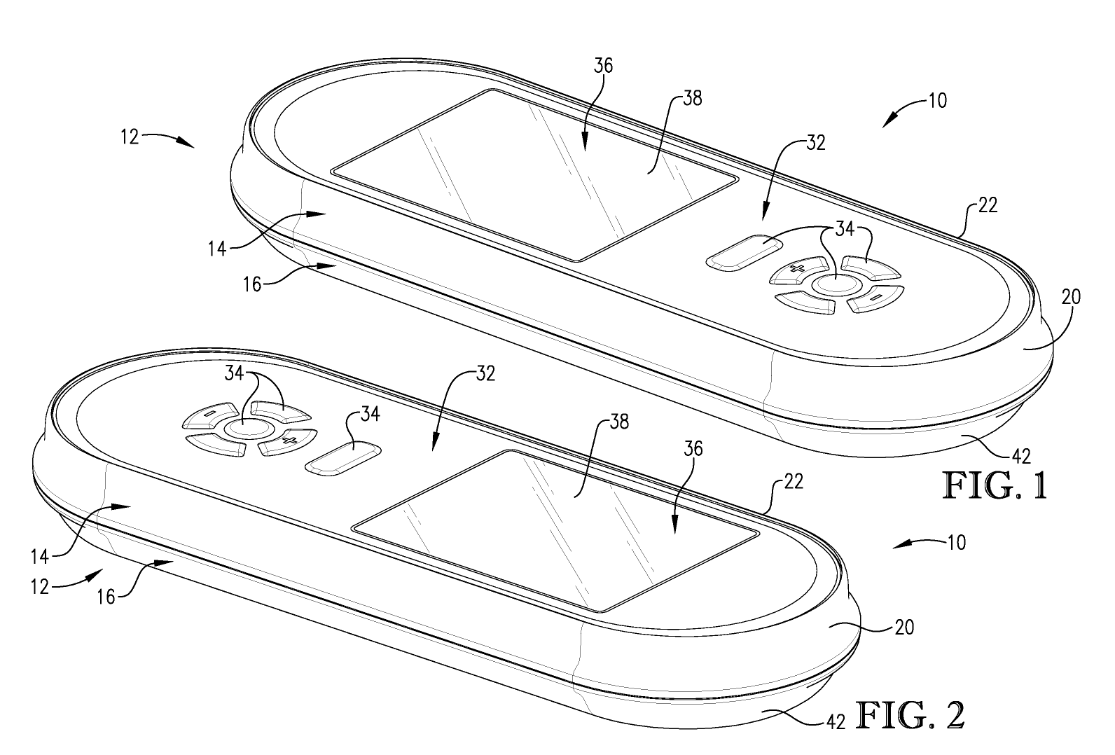

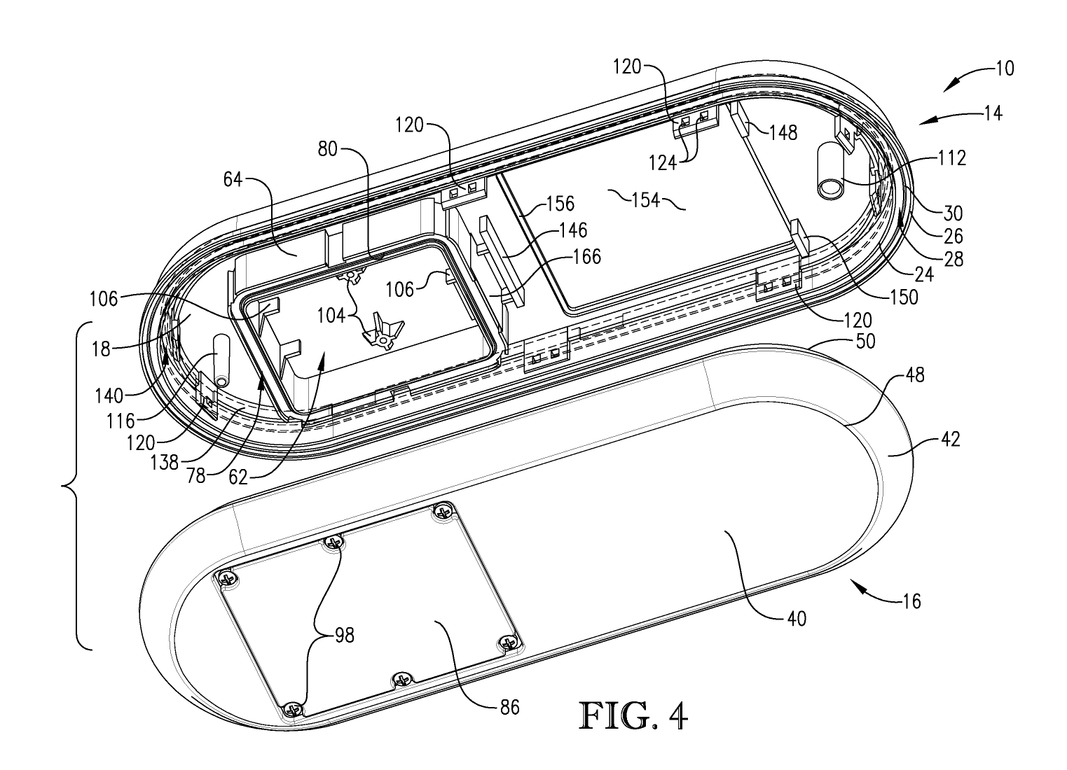

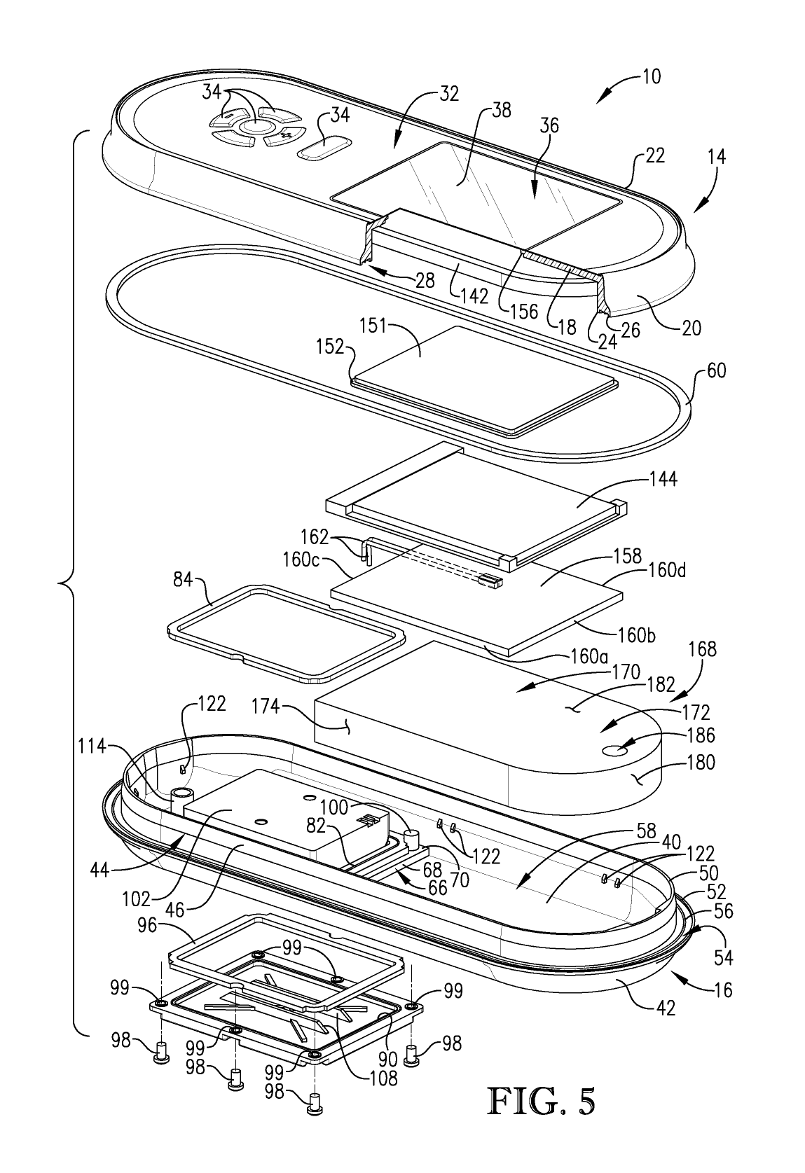

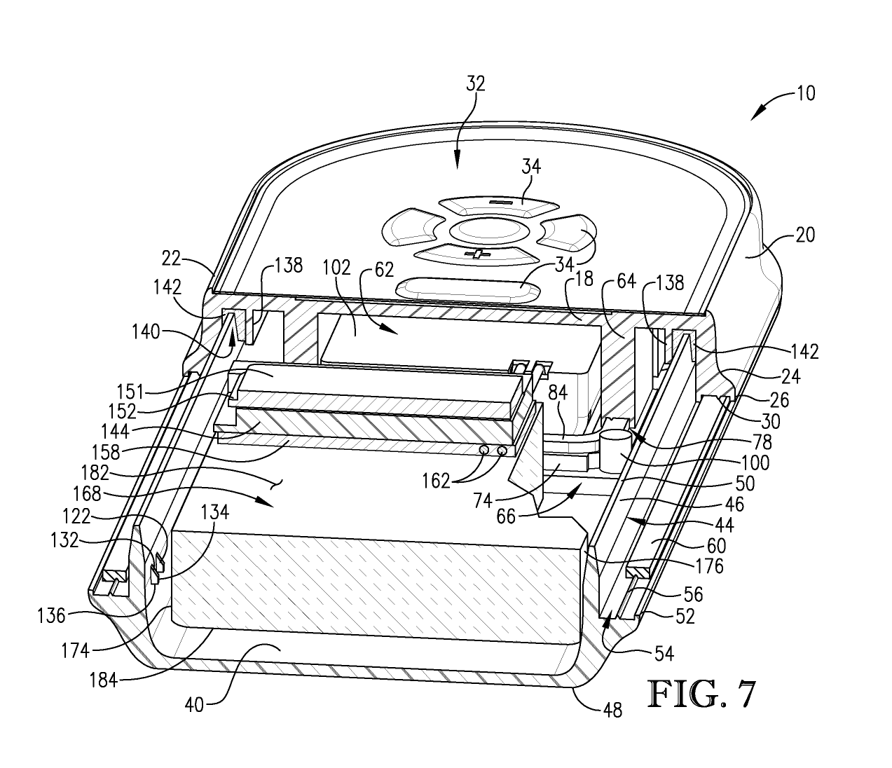

With initial reference to FIG. 1, a remote control 10 including a housing 12 is provided. The housing 12 includes an upper enclosure 14 and a lower enclosure 16. As shown in FIG. 7 and others, the upper enclosure 14 includes an upper wall 18 and a preferably continuous sidewall 20. The sidewall 20 has an upper margin 22 and inner and outer lower margins 24 and 26, respectively. In the illustrated embodiment, the upper wall 18 is positioned relative to the sidewall 20 so as to be recessed relative to the upper margin 22. However, a non-recessed structure is permissible. Preferably, a continuous perimetric groove 28 (best shown in FIGS. 4 and 5) having a rib 30 projecting therefrom is formed in the sidewall 20, with the groove 28 being recessed relative to the inner and outer lower margins 24 and 26, respectively.

In a preferred embodiment, a membrane switch assembly 32 is carried on the upper wall 18 of the upper enclosure 14. The membrane switch assembly 32 is preferably laminated to the upper wall 18 via a thermally cured adhesive, although other means of attachment fall within the scope of the present invention. The membrane switch assembly 32 preferably includes a plurality of buttons 34 which may be pressed by a user for transmittal of corresponding control signals. In the illustrated embodiment, the buttons 34 are raised to provide tactile feedback for the user. However, non-tactile membrane switches and other configurations of tactile membrane switches, including those fitted with springs or resilient domes below the buttons to provide both audible and tactile feedback to the user when the associated switch is activated, fall within the scope of the present invention. Other interfaces, such as capacitive touch interfaces, might suitably be used, as well. In a preferred embodiment, the membrane switch assembly 32 includes a display cover 36 including an at least substantially transparent window section 38, both of which will be discussed in more detail below. It is noted here, however, that it is within the scope of the present invention for the display cover 36 and window section 38 to be independent of the membrane switch assembly 32 or to be excluded from the remote control 10 entirely.

As shown in FIG. 7 and others, the lower enclosure 16 includes a lower wall 40 and a preferably continuous sidewall 42 including an upwardly extending projection 44. The projection 44 has a tapered end 46. The sidewall 42 has a lower margin 48 and inner and outer upper margins 50 and 52, respectively. Preferably, a continuous perimetric groove 54 having a rib 56 projecting therefrom is formed in the sidewall 42, with the groove 54 being recessed relative to the inner and outer upper margins 50 and 52, respectively.

The upper and lower enclosures 14 and 16, respectively, cooperatively define an interior compartment 58 when assembled. For assembly, a continuous housing gasket 60 is placed between the enclosures 14 and 16 such that the housing gasket 60 substantially fills both of the grooves 28 and 54 and is engaged by both of the ribs 30 and 56 to thereby provide a water-, air-, and dust-resistant seal between the environment and the interior compartment 58 when the enclosures 14 and 16 are assembled. In a preferred embodiment, the housing gasket 60 comprises rubber, although any one of a variety of alternative materials may be used without departing from the spirit of the present invention.

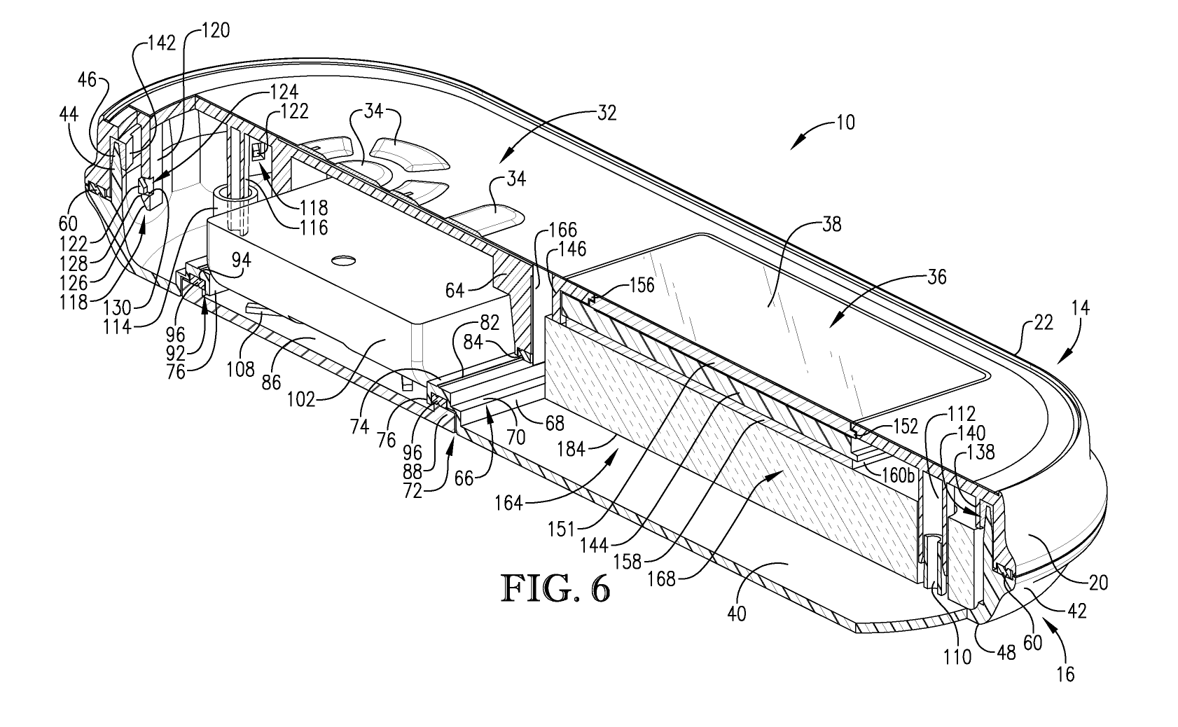

In a preferred embodiment, a battery compartment 62 is defined as described below. In a preferred embodiment, the upper enclosure 14 includes a substantially rectangular battery compartment body 64 (FIGS. 4, 6, and 7) projecting downwardly from the upper wall 18. Preferably, the lower enclosure 16 includes a battery cover receiving stepped portion 66 projecting from the lower wall 40 and including an outer wall 68 and an upper wall 70. The outer wall 68 defines a substantially rectangular opening 72 (FIG. 6) in the lower wall 40. The lower enclosure 16 also preferably includes a battery compartment base rail 74 extending inwardly and upwardly from the upper wall 70 of the stepped portion 66. The rail 74 has a lowermost portion 76 that preferably extends downwardly beyond the upper wall 70 of the stepped portion 66. Although rectangular forms are preferred, the battery compartment body 64, stepped portion 66, opening 72, and base rail 74 may be of any shape without departing from the spirit of the present invention. It is preferable, however, that the battery compartment body 64, stepped portion 66, opening 73, and base rail 74 be of similar shapes, for at least the reasons discussed below.

In a preferred embodiment and as best shown in FIGS. 4, 6, and 7, the battery compartment body 64 includes an at least substantially continuous perimetric groove 78 having a rib 80 projecting therefrom. The base rail 74 also includes a rib 82 projecting therefrom. A substantially rectangular battery compartment gasket 84 is positioned between the battery compartment body 64 and the rail 74 so as to be engaged by the respective ribs 80 and 82. A continuous seal is thereby formed between the battery compartment body 64 and the rail 74. In a preferred embodiment, the battery compartment gasket 84 comprises rubber, although any one of a variety of alternative materials may be used without departing from the spirit of the present invention.

In a preferred embodiment best shown in FIG. 6, a substantially rectangular removable battery cover 86 is positioned within the opening 72 defined by the stepped portion 66. An elevated edge 88 extends along the perimeter of the battery cover 86 and abuts or nearly abuts the upper and outer walls 68 and 70, respectively, of the stepped portion 66 and the lowermost portion 76 of the rail 74. A rib 90 projects from the elevated edge 88 of the battery cover 86, and an at least substantially continuous perimetric groove 92 having a rib 94 projecting therefrom is formed in the lower side of the rail 74. A substantially rectangular battery cover gasket 96 is positioned between the rail 74 and the elevated edge 88 so as to be engaged by the respective ribs 90 and 94. A substantially continuous seal is thereby formed between the battery cover 86 and the rail 74. In a preferred embodiment, the battery cover gasket 96 comprises rubber, although any one of a variety of alternative materials maybe used without departing from the spirit of the present invention.

In a preferred embodiment, the battery cover 86 is fixed to the lower enclosure 16 and, more particularly, to the stepped portion 66 by a plurality of screws 98 that pass through corresponding openings 99 and are received in corresponding columns 100. However, any one of a variety of alternative fastening or attachment means may be used without departing from the spirit of the present invention. For instance, the battery cover 86 might be attached using latches or by means of an interference fit.

In a preferred embodiment, the battery compartment body 64 is integral to the upper enclosure 14, while the stepped portion 66 and rail 74 are integral with the lower enclosure 16. However, it is within the scope of the present invention for non-integral arrangements to be used. For instance, the battery compartment body might be of entirely independent construction relative to the housing and be attached to the housing by latches, screws, adhesive, or other suitable means.

The battery compartment body 64, the rail 74, and the battery cover 86 cooperatively define the battery compartment 62. Thus, the battery cover gasket 96 seals the battery compartment 62 from the environment; and the battery compartment gasket 84 seals the interior compartment 58 from the battery compartment 62. A battery pack 102 is preferably positioned within the battery compartment 62 and is supported by support structures 104,106,108.

In a preferred embodiment, interengaging columns 110,112 and 114,116 extend from the enclosures 14 and 16 to position the enclosures 14 and 16 relative to each other and to prevent relative translational or rotational movement therebetween. The columns 110,112 and 114,116 are also operable to provide structural support in the case of extreme depression of the enclosures 14 and 16 relative to each other.

A plurality of resilient latches 118 are preferably provided to position and secure the upper and lower enclosures 14 and 16 relative to one another. In a preferred embodiment, each of the latches 118 comprises a latch body 120 and one or more corresponding nubs 122. As best shown in FIGS. 4 and 6, the latch bodies 120 extend downwardly from the upper wall 18 of the upper enclosure 14. One or more openings 124 is formed within each latch body 120. The plurality of nubs, each of which corresponds to one of the openings 124, is formed on the lower housing 12. The lower end of each latch body 120 includes an angled contact surface 126, a vertical flat contact surface 128, and a horizontal flat contact surface 130 (see FIG. 6); while the upper end of each nub 122 includes a corresponding angled contact surface 132, vertical flat contact surface 134, and horizontal flat contact surface 136 (see FIG. 7). When the upper enclosure 14 is lowered onto the lower enclosure 16, the two angled contact surfaces 126,132 interact such that the associated latch body 120 is resiliently elastically deformed inwardly and relative movement is accommodated. Engagement of the angled contact surfaces 126,132 is followed by engagement of the vertical flat contact surfaces 128,134, which is in turn followed by correspondence of the vertical flat contact surface 134 of the associated nub 122 with the associated opening 124. The latch body 120 reverses its inward deformation, returning to its normal configuration, such that the nub 122 is received within the opening 124. Reversal of the vertical movement (that is, upward movement of the upper enclosure 14 relative to the lower enclosure 16) is prevented by engagement of the horizontal flat contact surfaces 130 and 136.

In a preferred embodiment, a continuously extending perimetric inner wall 138 extends downwardly from the upper wall 18 of the upper enclosure 14 such that a continuously extending perimetric groove 140 is defined between the sidewall 20 and the inner wall 138. The groove 140 therefore circumscribes the interior compartment 58. As best shown in FIG. 4, portions of the inner wall 138 and the latch bodies 120 may be coextensive. However, independence of these components is also permissible. When the enclosures 14 and 16 are assembled, the upwardly extending projection 44 of the lower enclosure 16 is received within the groove 140. A polymer bead 142 is formed within the groove 140 such that the bead 142 substantially encompasses the tapered end 46 of the projection 44. Preferably, the polymer bead 142 is an epoxy bead that, when cured, secures the enclosures 14 and 16 to each other and forms a continuous water-, air-, and dust-tight seal between the enclosures. Those of ordinary skill in the art will appreciate that the bead 142 may be formed of any other suitable seal material.

Positioning, attachment, and sealing of the enclosures 14 and 16 relative to one another is thereby accomplished by four complementary means: the housing gasket 60, the bead 142, the latches 118, and the interengaging columns 110,112 and 114,116.

Turning now to FIG. 6, the remote control 10 preferably includes a display assembly 144, although it is permissible within the scope of the invention for no display assembly to be provided. In a preferred embodiment, the display cover 36 discussed previously is positioned above and protects the display assembly 144. The display assembly 144 is visible through the window section 38 of the display cover 36. Preferably, the display assembly 144 includes a liquid crystal display (LCD) screen, although a variety of display types are within the scope of the present invention. As best shown in FIG. 4, several structures are preferably provided to aid in lateral positioning of the display assembly 144. For instance, a barricade 146 is provided to prevent lateral motion toward the battery compartment 62; and a pair of blocks 148,150 are provided to prevent lateral motion away from the battery compartment 62. However, it is within the scope of the present invention for any suitable means for positioning to be used. For instance, a different configuration of positioning structures would be permissible, or the display might be fixed using fasteners or adhesive.

In a preferred embodiment, an at least substantially transparent filler plate 151 is positioned below the window section 38 in an interposed relationship between the display assembly 144 and the display cover 36, with the filler plate 151 contacting the window section 38 so as to at least substantially eliminate any air gap along an underside of the window section 38. Elimination of air between the window section 38 and the display assembly 144 reduces the risk of condensation buildup along the underside of the window section 38. The filler plate 151 preferably comprises a polycarbonate material, although glass or other materials are within the ambit of the present invention, and includes an outwardly extending flange 152. Although other relative positioning is permissible, it is preferable that the filler plate 151 is positioned in an opening 154 formed in the upper wall 18 of the upper enclosure 14 so as to be circumscribed by the upper wall 18. In a preferred embodiment and as best shown in FIG. 6, the upper enclosure 14 includes an inwardly extending overhanging portion 156 that in part defines the opening 154. Upon insertion of the filler plate 151 in the opening 154, the flange 152 abuts the overhanging portion 156 such that further movement of the filler plate 151 toward the display cover 36 is restricted.

Positioned below the display assembly 144 is a control board 158 having side faces 160a,160b,160c,160d (see FIG. 5). In a preferred embodiment, the control board 158 is a printed circuit board. However, the control board 158 can be of any suitable configuration for controlling the remote control 10. For instance, a control board could be provided that includes a base with any desired electronic components, such as an electronic controller or microprocessor, mounted thereon. The board could feature printed circuitry, or the electronic components could be linked by discrete wires. In the illustrated embodiment, wiring 162 is provided between the battery pack 102 and the control board 158 such that the battery pack 102 supplies power to the control board 158.

A critical space 164 in which water or humid air ingress would be particularly problematic is defined within the interior compartment 58 by the control board 158 and the lower wall 40 of the lower enclosure 16. More particularly, as best shown in FIG. 6, the critical space 164 is the region bounded above and below by the control board 158 and the lower wall 40, respectively, and at the sides by the theoretical projection of the side faces 160a,160b,160c,160d of the control board 158. In other words, the critical space 164 is that found directly below the control board 158.

In a preferred embodiment, a flex cable 166, shown in a simplified schematic form in FIGS. 4 and 6, is provided between the membrane switch assembly 32 and the control board 158 for the transmittal of signals from the buttons 34 to the control board 158. Although the specific means by which the flex cable 166 connects to the membrane switch assembly 32 and the control board 158 are not illustrated, any means known in the art fall within the scope of the present invention. Furthermore, appropriate connection means are not to be limited to flex cables alone.

In a preferred embodiment, potting of the control board 158 and its associated electronic components in an epoxy or other material, as is often done for waterproofing, is unnecessary and consequently avoided. However, it is within the scope of the present invention for the control board 158 and/or its associated components to be potted or configured in any traditional or non-traditional manner.

A foam insert 168 is provided between the control board 158 and the lower wall 40 of the lower enclosure 16. In a preferred embodiment, the insert 168 includes a rectangular portion 170 and a semicircular portion 172, the two portions being connected so as to form a half obround. The rectangular portion 170 includes side surfaces 174 and 176 and a base surface 178, while the semicircular portion includes an arcuate surface 180. The rectangular and semicircular portions 170 and 172, respectively, cooperatively define a shared upper surface 182 and a shared lower surface 184. However, it is within the ambit of the present invention for the foam insert to be of a different shape than that described above. The foam insert 168 preferably comprises a low durometer foam such as closed-cell polyvinyl chloride (PVC) foam. However, use of other types of foam falls within the scope of the present invention.

The insert 168 is preferably sized such that it substantially fills the interior compartment 58 and completely fills the critical space 164 within the interior compartment 58. Furthermore, the insert 168 is preferably under a compressive load when positioned as shown.

More particularly, the upper surface 182 of the insert 168 is preferably in contact with the control board 158, and the lower surface 184 of the insert 168 is preferably in contact with the lower wall 40 of the lower enclosure 16. Preferably, the uncompressed distance between the upper surface 182 and the lower surface 184 is greater than that between the control board 158 and the lower wall 40, such that the insert 168 is compressed between the lower wall 40 and the control board 158 when positioned therebetween. The insert 168 therefore exerts a force on adjacent structures, including the control board 158, such that the insert 168 secures the control board 158 in place. Additional fixation means for securing the control board 158 are unnecessary and preferably are avoided, although they are allowable with respect to certain aspects of the present invention. The insert 168 is also operable to secure in place structures adjacent the control board 158. In a preferred embodiment, these structures include the display assembly 144 and the filler plate 151. Particularly, the compressive load on the insert 168 exerts the holding force against the control board 158, which in turn transfers the force to the display assembly 144 and the filler plate 151.

Positioning of the insert 168 is aided by the insertion of the interengaging columns 110,112 in a hole 186 formed in the insert 168. In the illustrated embodiment, the hole 186 is formed in the semicircular portion 172, although the hole 186 may be formed in any portion of the insert 168 without departing from the spirit of the present invention. The rectangular portion 170 is preferably positioned below the control board 158 so as to completely fill the critical space 164, with the base surface 178 of the rectangular portion 170 abutting the outer wall 68 of the stepped portion 66 that projects from the lower wall 40 of the lower enclosure 16.

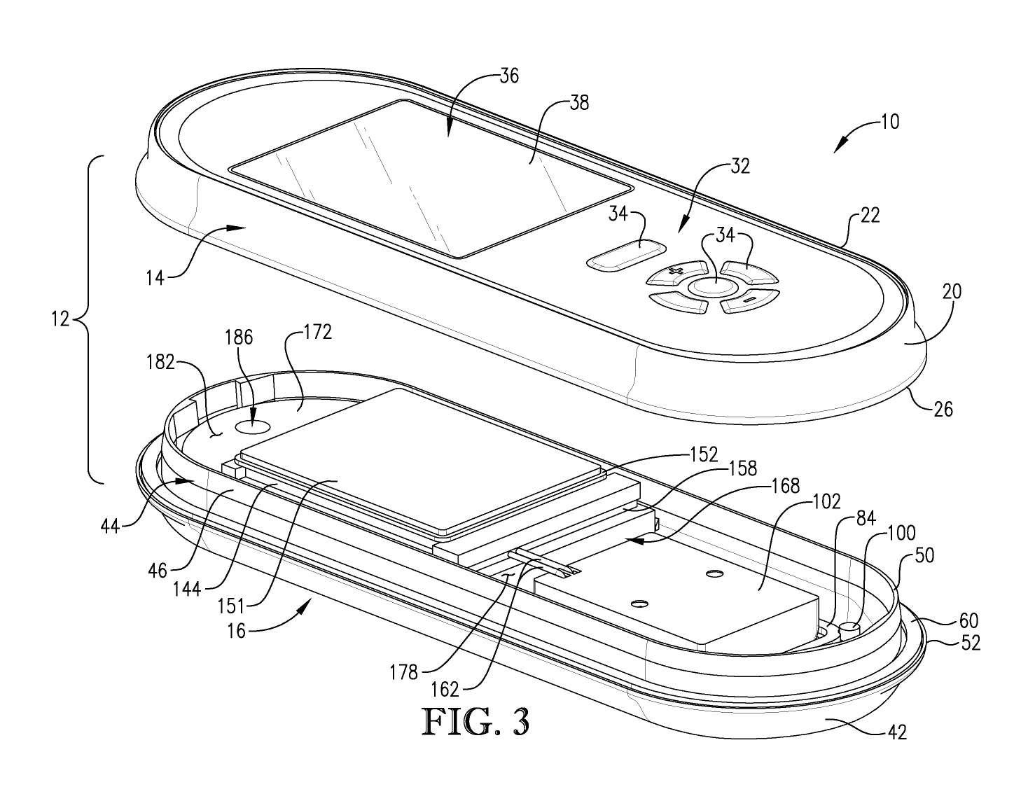

In a preferred method of assembly of the preferred embodiment shown in FIGS. 1-7, the membrane switch assembly 32 is first laminated to the upper wall 18 of the upper enclosure 14. The upper enclosure 14 is then manipulated such that the membrane switch assembly faces down. The filler plate 151 is placed in the opening 154 in the upper wall 18 of the upper enclosure 14 such that the flange 152 abuts the overhanging portion 156, the display assembly 144 is placed on the filler plate 151, and the control board 158 is placed on the display assembly 144. The battery pack 102 is then placed in the battery compartment 62. The housing gasket 60 is placed in the upper enclosure groove 28, the battery compartment gasket 84 is placed in the battery compartment body groove 78, and the foam insert 168 is placed in the interior compartment 58 such that the interengaging columns 110,112 are received in the hole 186.

Epoxy (uncured) is then inserted into the groove 140 in the upper enclosure 14. Immediately or shortly thereafter, the lower enclosure 16 is placed on the upper enclosure 14. Appropriate positioning and initial securement is accomplished by the interaction of the columns 110,112 and 114,116; the placement of the projection 44 in the groove 140; and the engagement of the latch bodies 120 by the corresponding nubs 122.

Appropriate positioning ensures that the housing gasket 60 is cooperatively received within the grooves 28 and 54 of the upper enclosure 14 and lower enclosure 16, respectively, and engaged by the associated ribs 30 and 56. Appropriate positioning also ensures that the battery compartment gasket 84 is placed in alignment with the rail 74 such that the rail 74 and its rib 82 cooperate with the groove 78 and rib 80 of the battery compartment body 64 to engage the battery compartment gasket 84. Even further, appropriate positioning ensures that the projection 44 is received in the groove 140.

Placement of the projection 44 in the groove 140 leads to distribution of the epoxy carried in the groove 140 about the projection 44 such that the epoxy substantially encompasses the projection 44. The epoxy is then allowed to cure, during which time the aforementioned positioning and initial securement means ensure stability of the housing 12. Upon curing of the epoxy, an epoxy (polymer) bead 142 is thus formed that substantially encompasses the projection 44 and bonds the projection 44 to the surfaces defining the groove 140, thus additionally securing the upper enclosure 14 to the lower enclosure 16 and providing a seal therebetween.

Next, the battery cover gasket 96 is placed in the groove 92 on the underside of the rail 74 such that is engaged by the associated rib 94, and the battery cover 86 is placed on top of the battery cover gasket 96 such the associated rib 90 engages the battery cover gasket 96 and the elevated edge 88 abuts both the outer wall 68 and the upper wall 70 of the battery cover receiving stepped portion 66. Finally, a plurality of screws 98 are inserted through the openings 99 and into the columns 100 to secure the battery cover 86 in place.

It will be appreciated that the sequence of assembly may be suitably altered without departing from the spirit of the present invention.

The preferred forms of the invention described above are to be used as illustration only and should not be utilized in a limiting sense in interpreting the scope of the present invention. Obvious modifications to the exemplary embodiments, as hereinabove set forth, could be readily made by those skilled in the art without departing from the spirit of the present invention.

The inventors hereby state their intent to rely on the Doctrine of Equivalents to determine and access the reasonably fair scope of the present invention as pertains to any apparatus not materially departing from but outside the literal scope of the invention set forth in the following claims.

What is claimed is:

1. A remote control for use in a high-humidity environment, said remote control comprising:
a housing defining an interior compartment;
a control board positioned within the interior compartment, with the control board occupying only part of the interior compartment such that an unoccupied remaining portion of the interior compartment is defined; and
a foam insert located within the interior compartment such that the insert is positioned at least in part adjacent the control board,
said foam insert being resiliently loaded to thereby exert a force against the control board and thus secure the control board within the interior compartment,
said foam insert configured to at least substantially fill the remaining portion of the interior compartment to thereby at least substantially prevent formation of condensate within the remaining portion of the interior compartment.

2. The remote control as claimed in claim 1,
wherein the foam insert is compressed between the housing and the control board.

3. The remote control as claimed in claim 1,
said remaining portion of the interior compartment including a critical space extending between the control board and the housing,
said foam insert configured to fill the critical space to thereby at least substantially prevent formation of condensate within the critical space.

4. The remote control as claimed in claim 1,
wherein the foam insert includes a rectangular portion adjacent a semicircular portion,
said rectangular portion including a base surface and a pair of side surfaces,
said semicircular portion including an arcuate surface,
said rectangular portion and said semicircular portion including a shared upper surface and a shared lower surface.

5. The remote control as claimed in claim 4,
wherein the rectangular portion is positioned adjacent the control board.

6. The remote control as claimed in claim 4,
wherein a positioning hole is formed in the semicircular portion.

7. The remote control as claimed in claim 4,
said housing including
a lower wall,
a sidewall, and
a stepped portion,
said upper surface of the insert contacting the control board,
said lower surface of the insert contacting the lower wall,
said arcuate surface of the insert and said side surfaces of the insert contacting the sidewall,
said base surface of the insert contacting the step portion,
said lower wall, sidewall, stepped portion, and control board thereby cooperatively positioning the foam insert within the remaining portion of the interior compartment.

8. The remote control as claimed in claim 1,
said remote control including a display assembly positioned at least in part adjacent the control board,
said force exerted by the foam insert serving to also secure the display assembly within the interior compartment.

9. The remote control as claimed in claim 1,
said housing defining a battery compartment,
said foam insert being positioned adjacent the battery compartment.

10. The remote control as claimed in claim 1,
wherein the foam insert comprises closed-cell polyvinyl chloride.

11. The remote control as claimed in claim 1,
wherein the remote control is devoid of mechanical fasteners for securing the control board.

12. The remote control of claim 1,
wherein the control board comprises electronic components mounted on a printed circuit board.

13. A remote control for use in a high-humidity environment, said remote control comprising:
a housing comprising a pair of interconnected enclosures that cooperatively define an interior compartment,
said enclosures including complementary latch components that secure the enclosures to one another;
a control board positioned within the interior compartment,
a first one of said enclosures including an at least substantially continuous groove that at least substantially circumscribes the interior compartment,
a second one of said enclosures including an at least substantially continuous projection received within the groove; and
a polymer bead being formed within the groove such that the bead at least partially encompasses the projection, the bead and the projection thereby cooperating to additionally secure the enclosures to each other and to form an at least substantially continuous seal between the enclosures.

14. The remote control of claim 13,
said polymer bead comprising an epoxy.

15. The remote control of claim 13,
said latch components being arranged in pairs of interconnecting first and second components arranged on respective ones of the enclosures,
said first components comprising an apertured projection and said second component comprising a nub, with each of the nubs being received in an aperture of the interconnecting projection.

16. The remote control of claim 13,
said remote control including an at least substantially continuous housing gasket positioned between the enclosures and at least substantially circumscribing the interior compartment to thereby provide a seal between the interior compartment and the environment.

17. The remote control of claim 13,
said remote control including a removable battery cover,
said enclosures and said battery cover cooperatively defining a battery compartment.

18. The remote control of claim 17,
said remote control including a battery pack received within the battery compartment.

19. The remote control of claim 17,
said remote control including an at least substantially continuous battery compartment gasket positioned between the enclosures and at least substantially circumscribing the battery compartment to thereby provide a seal between the interior compartment and the battery compartment.

20. The remote control of claim 17,
one of said enclosures defining a battery compartment access opening, with the battery cover serving to cover the access opening when attached to the one enclosure,
said remote control including an at least substantially continuous battery cover gasket positioned between the battery cover and said one of the enclosures and at least substantially circumscribing the battery compartment to thereby provide a seal between the battery compartment and the environment.

21. The remote control of claim 13,
said remote control including a display and a cover disposed in a covering relationship relative the display,
said cover including a substantially transparent window section in general alignment with the display.

22. The remote control of claim 21,
said display being an LCD screen.

23. The remote control of claim 21,
said remote control including a substantially transparent filler plate underlying the window section in an interposed relationship between the display and the cover, with the filler plate contacting the window section so as to at least substantially eliminate any air gap along an underside of the window section, thereby permitting the display to be visible through the window section while reducing the risk of condensation buildup along the underside of the window section.

24. The remote control of claim 13,
said remote control including a membrane switch assembly.

25. The remote control of claim 24,
said membrane switch assembly being laminated to one of the enclosures using a thermally cured adhesive.

26. The remote control of claim 13,
said remote control including a foam insert located within the interior compartment such that the insert is positioned at least in part adjacent the control board,
said foam insert being resiliently loaded to thereby exert a force against the control board and thus secure the control board within the interior compartment,
said control board occupying only part of the interior compartment such that an unoccupied remaining portion of the interior compartment is defined,
said foam insert configured to at least substantially fill the remaining portion of the interior compartment to thereby at least substantially prevent formation of condensate within the remaining portion of the interior compartment.
